(19) United States
(12) Patent Application Publication
(10) Pub. No.: US 2025/0201754 A1
(43) Pub. Date: Jun. 19, 2025

(54) SEMICONDUCTOR DEVICE COMPRISING A CARRIER, A SEMICONDUCTOR DIE AND A C-SHAPED CLIP CONNECTED BETWEEN THEM

(71) Applicant: Infineon Technologies AG, Neubiberg (DE)

(72) Inventors: Joon Shyan TAN, Seremban (MY); Thai Kee GAN, Melaka (MY); Lee Shuang WANG, Bukit Baru (MY); Azlina KASSIM, Cheng (MY); Hui Wen GOH, Cheng (MY); Mei Fen HIEW, Paya Rumput (MY); Sin Fah YAP, Parit (MY)

(73) Assignee: Infineon Technologies AG, Neubiberg (DE)

(21) Appl. No.: 18/968,398

(22) Filed: Dec. 4, 2024

(30) Foreign Application Priority Data
Dec. 19, 2023 (DE) 10 2023 135 840.5

(51) Int. Cl. H01L 23/00; H01L 23/31; H01L 23/495

(52) U.S. Cl. CPC H01L 24/37; H01L 23/49541; H01L 24/40; H01L 24/84; H01L 23/3107; H01L 2224/37012; H01L 2224/40248; H01L 2224/84138

(57) ABSTRACT

A semiconductor device comprising a carrier, a semiconductor die disposed on the carrier and comprising a first contact pad on a first main face remote from the carrier, and a clip. The clip comprises a horizontal portion, a vertical portion, and a bent-back portion connected with the carrier.

### CROSS-REFERENCE TO RELATED APPLICATION

This Utility Patent application claims priority to German Patent Application No. 10 2023 135 840.5 filed Dec. 19, 2023, which is incorporated herein by reference.

### TECHNICAL FIELD

The present disclosure is related to a semiconductor device comprising a carrier, a semiconductor die disposed on the carrier and a clip connected between the semiconductor die and the carrier.

### BACKGROUND

Power semiconductor packages include a power semiconductor die, in particular a power semiconductor transistor die, connected with a die carrier like a leadframe and embedded in a mold compound. A contact pad of the semiconductor transistor die like, for example, a source pad or a drain pad, is connected via a connector element with a die pad or a lead of the leadframe. Due to the high currents of up to 10A and higher flowing in the load path of the semiconductor transistor, the selection of a suitable connection element and its connection to the semiconductor die as well as to the leadframe is of very high importance.

### SUMMARY

A first aspect of the present disclosure is related to a semiconductor device comprising a carrier, a semiconductor die disposed on the carrier and comprising a first contact pad on a first main face remote from the carrier, and a clip, wherein the clip comprises a horizontal portion, a vertical portion, and a bent-back portion.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 comprises FIGS. 1A and 1B and shows a cross-sectional view (A) and a top-down view (B) on an example of a leadframe to be used as part of a semiconductor device according to the first aspect.

FIG. 2 comprises FIGS. 2A and 2B and shows a cross-sectional view of a examples of semiconductor devices comprising two clips with upper surfaces not exposed to the outside (FIG. 2A), and upper surfaces exposed to the outside (FIG. 2B).

FIG. 3 comprises FIGS. 3A and 3B and shows a cross-sectional view of examples of semiconductor devices comprising one clip connected between the source pad and the die pad (FIG. 3A), and connected between the drain pad and the die pad (FIG. 3B).

FIG. 4 comprises FIGS. 4A to 4C and shows cross-sectional side views of different configurations of interacting bent-back portions and carrier connection portions.

FIG. 5 comprises FIGS. 5A to 5C and shows different kinds of clips to be used in a semiconductor device according to the first aspect.

### DETAILED DESCRIPTION

A first aspect of the present disclosure is related to a semiconductor device comprising a carrier, a semiconductor die disposed on the carrier and comprising a first contact pad on a first main face remote from the carrier, and a clip, wherein the clip comprises a horizontal portion, a vertical portion, and a bent-back portion.

Due to its dimensions and its coupling with the carrier, the clip enables very high currents flowing through the load path of the transistor to be passed on. In particular, the clip may have a C-shape in which the bent-back portion is formed as a horizontal bar and thus rests on the die carrier with its entire lower surface. The carrier may further comprise a carrier connection portion for connecting with the bent-back portion of the clip and thus further increasing the coupling between the clip and the carrier. Another advantage of a clip shaped as described is that the clip is shorter when viewed from the side than a non-bent clip, providing additional space for larger semi-conductors.

According to an embodiment of the semiconductor device of the first aspect, the carrier comprises a leadframe comprising a die pad and one or more leads. The clip can be connected with the die pad and the further clip can be connected to a lead.

According to another embodiment the carrier can also be one of a direct copper bond (DCB), an active metal braze (AMB), or an isolated metal substrate (IMS).

According to an embodiment of the semiconductor device of the first aspect, the semiconductor device further comprises an encapsulant covering at least parts of the semiconductor die, the carrier, and the clip. According to an example thereof, the encapsulant covers an outer sidewall of the vertical portion of the clip. In case of the carrier being a leadframe with a die pad and one or more leads, the encapsulant can also be filled in between the die pad and the one or more leads and also between the leads.

According to an embodiment of the semiconductor device of the first aspect, a surface of the horizontal portion of the clip is exposed to the outside thus allowing top side cooling by attaching a suitable heatsink on the surface of the horizontal portion.

According to an embodiment of the semiconductor device of the first aspect, the semiconductor die comprises a semiconductor transistor die. According to further examples thereof, the semiconductor die comprises one or more of a horizontal semiconductor transistor die, a vertical semiconductor transistor die, a semiconductor power transistor die, an IGBT die, a MOSFET die, a CoolMOS die, a wide band gap semiconductor transistor die, in particular a SiC transistor die or a GaN transistor die.

According to an embodiment of the semiconductor device of the first aspect, the semiconductor die comprises only one contact pad on the first main face. This can in particular be the case if the semiconductor die is a vertical semiconductor transistor die comprising a source pad on the first upper main face and a drain pad on the second lower main face, or in a so-called source-down configuration a drain pad on the first upper main face and a source pad on the second lower main face.

According to an embodiment of the semiconductor device of the first aspect, the semiconductor die comprises a second contact pad on the first main face. This can in particular be the case if the semiconductor die is a horizontal MOSFET die comprising a source pad and a drain pad both being disposed on the first upper main face of the semiconductor die.

According to an embodiment of the semiconductor device of the first aspect, the semiconductor device further comprises a second clip connected between the second contact pad and the carrier. According to an example thereof, the second clip can be similar in shape to the first clip.

A second aspect of the present disclosure is related to a method for fabricating a semiconductor device, the method comprising providing a carrier, disposing a semiconductor die on the carrier, the semiconductor die comprising a first contact pad on a first main face remote from the carrier, providing a clip comprising a horizontal portion, a horizontal portion, an adjoining vertical portion, and an adjoining a bent-back portion connected with the carrier, and connecting the clip between the semiconductor die and the carrier by connecting the horizontal portion with the contact pad and the bent-back portion with the carrier.

According to an embodiment of the method of the second aspect, providing the carrier comprises forming a carrier connection portion into the carrier, the carrier connection portion being configured to connect with the bent-back portion of the clip. According to an example thereof, the carrier connection portion comprises a recess which may be formed by one of coining, milling or etching.

According to an embodiment of the method of the second aspect, the method further comprising covering at least parts of the semiconductor die, the carrier, and the clip with an encapsulant. According to an example thereof, the method further comprises covering an outer sidewall of the vertical portion of the clip with the encapsulant.

According to an embodiment of the method of the second aspect, in case of a second contact pad on a first upper main face of the semiconductor die, the method further comprises connecting a second clip between the second contact pad and the die pad or a lead. The second clip can have a similar shape like the first clip.

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the varius exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

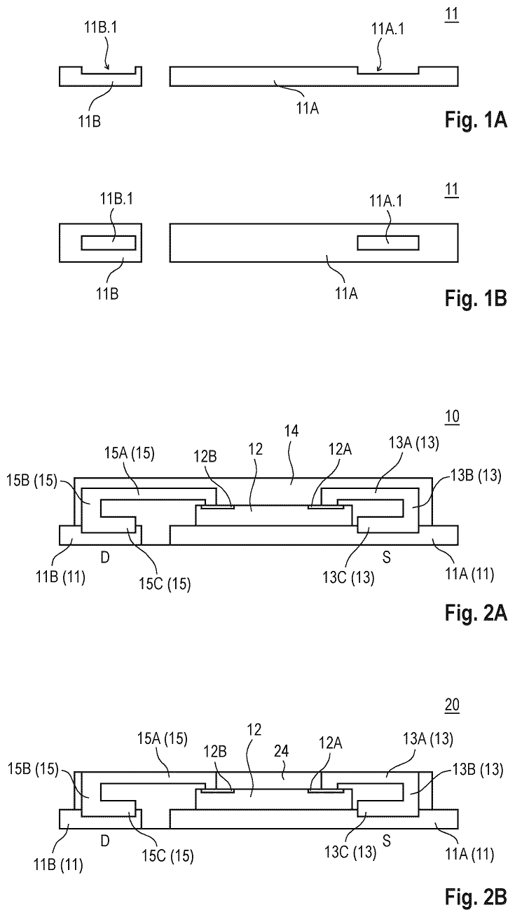

FIG. 1 comprises FIGS. 1A and 1B and shows a cross-sectional view (A) and a top-down view (B) on an example of a leadframe to be used as part of a semiconductor device according to the first aspect. Other types of carriers such as DCB (direct copper bond), an AMB (active metal brazed), or IMS (insulated metal substrate) can also be used.

The leadframe 11 as shown in FIG. 1 is, for example, made of Cu or a Cu alloy, possibly with a Ni plating on its surfaces, and comprises a die pad 11A and one or more leads 11B. As a special feature both the die pad 11A and the lead 11B may each comprise a recess 11A.1 and 11B.1 formed in their upper surfaces. The recesses 11A.1 and 11B.1 serve as contact regions configured to receive the lower ends of the clips 13 and 15 (see FIG. 2). As can be seen in particular in FIG. 1B, the recesses 11A.1 and 11B.1 may be formed as slots which are slightly bigger in their dimensions than the lower ends of the clips 13 and 15. The depth of the recesses 11A.1 and 11B.1 can be in a range from 10 μm to 100 μm. The recesses can be produced by coining, milling or etching. This way of connecting the clips 13 and 15 to the die pad 11A and the conductor 11B increases the contact area between the clips 13 and 15 and the die pad 11A and the lead 11B. This can reduce the drain-source on resistance RDS(on) of the transistor. In addition, the thermal coupling and thus the heat dissipation downwards can be improved. The recesses 11A.1 and 11B.1 are furthermore advantageous in that they can serve as a guideline for placement of the clips 13 and 15.

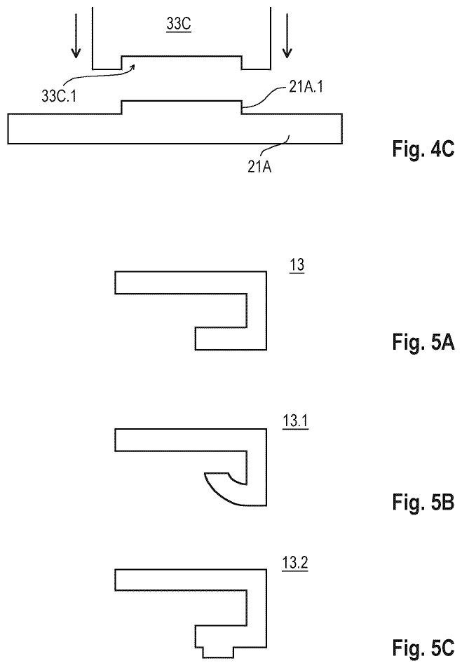

In the embodiment described above the bent-back portion 13C comprises a flat lower surface and rests completely in the recess 11A.1 or 11B.1, see also FIG. 4A below. In another embodiment the bent-back portion 13C comprises an elevation at its lower surface and only the elevation rests within the recesses 11A.1 or 11B.1, see also FIG. 4B below.

In another embodiment the carrier connection portion comprises a strip-like elevation on an upper surface of the carrier and the bent-back portion comprises a recess with dimensions slightly bigger than the strip-like elevation of the carrier, wherein the strip-like elevation engages with the slot when connecting the bent-back portion with the carrier, see also FIG. 4C below.

FIG. 2 comprises FIGS. 2A and 2B and shows a cross-sectional view of a examples of semiconductor devices comprising two clips with upper surfaces not exposed to the outside (FIG. 2A), and upper surfaces exposed to the outside (FIG. 2B).

In particular, FIG. 2A shows a semiconductor device 10 comprising a leadframe 11 which comprising a die pad 11A and one or more leads 11B. A semiconductor die 12 is disposed on the die pad 11A and comprises a source pad 12A and a drain pad 12B both disposed on a first upper main face. A first clip 13 is connected between the source pad 12A and the die pad 11A, and a second clip 15 is connected between the drain pad 12B and one of the leads 11B. The clip 13 comprises a horizontal portion 13A connected with the contact pad 12A, a vertical portion 13B, and a bent-back portion 13C connected with the die pad 11A. In this embodiment the bent-back portion 13C comprises the form of a horizontal bar. The lower end of the bent-back portion 13C engages in the recess 11A.1 of the die pad 11A. The second clip 15 comprises a similar shape and in the same way the lower end of the bent-back portion 15C engages in the recess 11B.1 of the lead 11B. Furthermore an encapsulant 14 covers parts of the semiconductor die 12, the leadframe carrier 11, and the clip 13. The encapsulant 14 also covers the top surfaces of the first and second clips 13 and 15 so that they are not exposed to the outside. Thus in the operation of the device only bottom side cooling is possible.

The semiconductor die 12 is, for example, a lateral MOSFET die comprising source pad 12A and drain pad 12B on one and the same first upper main face of the semiconductor die 12.

FIG. 2B shows a semiconductor device 20 that is similar in structure to the semiconductor device 10 of FIG. 1, so that most of the reference numerals have been adopted unchanged. The only difference is that the top surfaces of the first and second clip 13 and 15 are exposed to the outside instead of being covered by the encapsulant 14 thus providing a top surface for heat dissipation. This variant allows a heat sink to be mounted on the top surface of the device to provide also top side cooling so that as a result double side cooling is possible. In some embodiments, the top surfaces of the first and second clips 13 and 15 may be exposed grinding the upper part of the encapsulant until a level of the top surfaces of the clips 13 and 15 is reached.

The encapsulant 14 or 24 may be comprised of a conventional mold compound like, for example, a resin material, in particular an epoxy resin material. Moreover, the encapsulant 14 can be made of a thermally conductive material to allow efficient heat dissipation to external application heat sinks. The material of the encapsulant 14 can, in particular, comprise a resin like an epoxy resin material filled with particles like, for example, SiO or other ceramic particles, or thermally conductive particles like, for examples, Al₂O₃, BN, AlN, Si₃N₄, diamond, or any other thermally conductive particles.

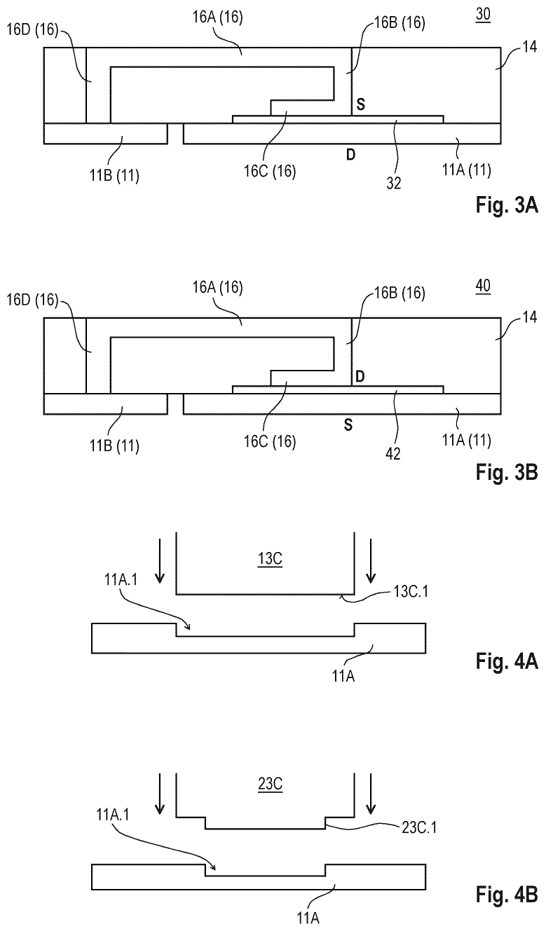

FIG. 3 comprises FIGS. 3A and 3B and shows a cross-sectional view of examples of semiconductor devices comprising only one clip connected between the source pad and the die pad (FIG. 3A), and connected between the drain pad and the die pad (FIG. 3B).

FIGS. 3A and 3B show semiconductor devices 30 and 40 that are similar in structure to the semiconductor devices 10 and 20 of FIGS. 1 and 2, so that most of the reference numerals have been adopted unchanged. The only difference is that the semiconductor dies 32 and 42 are vertical transistor devices which comprise only one contact pad of the load path at an upper main surface thereof and another contact pad of the load path at a lower main face. The contact pads themselves are not shown in the Figs. The difference between the semiconductor devices 30 and 40 is that in the semiconductor die 32 the source pad is disposed at the upper main face (indicated by the letter “S”) and the drain pad at the lower main face whereas in the semiconductor die 42 the drain pad is disposed at the upper main face (indicated by the letter “D”) and the source pad at the lower main face, a configuration which is also called source-down configuration. For attaching the semiconductor dies 32 and 42 to the leadframe 11, a solder, e.g. a solder paste or a diffusion solder can be used.

Hence in both devices 30 and 40 the semiconductor die 32 or 42 is connected with its backside with the die pad 11A and there is only one clip 16 which is connected between the contact pad at the upper main face and a lead 11B of the carrier 11. The clip 16 comprises a C shape on the right hand side, and in particular a horizontal portion 16A, a first vertical portion 16B connected with the horizontal portion 16A on its right hand side, a horizontal bent-back portion 16C which is connected with the first vertical portion 16B and which is connected with the source pad of the semiconductor die 32 according to FIG. 3A and with the drain pad of the semiconductor die 42 according to FIG. 3B. The clip 16 furthermore comprises a second vertical portion 16D which is connected with the horizontal portion 16A on its left hand side and which is connected with the lead 11B of the carrier 11. As shown in FIGS. 3A and 3B, an upper surface of the horizontal portion 15A is exposed to the outside. However, it can also be the case that the upper surface of the horizontal portion 15A is covered by the encapsulant 14.

FIG. 4 comprises FIGS. 4A to 4C and shows cross-sectional side views of different configurations of interacting bent-back portions and carrier connection portions. As indicated by the arrows, FIGS. 4A to 4C each show the lower portion of the bent-back portion and the carrier connection portion in a situation just before insertion of the lowe portion of the bent-back portion into the carrier connection portion. Not shown are any connection layers that might be used such as a solder layer or a sinter layer applied onto one or both of the surfaces to be connected.

FIG. 4A shows the embodiment of FIGS. 1 and 2 wherein the carrier 11A comprises a recess 11A.1 and the bent-back portion 13C comprises a flat lower surface 13C.1 so that a lower part of the bent-back portion 13C corresponding to the depth of the recess 11A.1 rests completely in the recess 11A.1.

FIG. 4B shows another embodiment in which the carrier 11A comprises a recess 11A.1 like in FIG. 4A. However, here the bent-back portion 23C does not comprise a flat lower surface but instead a protruding portion 23C.1 which rests completely in the recess 11A.1. The width of the protruding portion 23C.1 is slightly smaller than the width of the recess 11A.1 and the height of the protruding portion 23C.1 corresponds to the depth of the recess 11A.1.

FIG. 4C shows another embodiment in which the carrier 11A comprises a protruding portion 21A.1 on a upper surface thereof. The bent-back portion 33C comprises a recess 33C.1 on a lower surface thereof. The width of the protruding portion 21A.1 is slightly smaller than the width of the recess 33C.1 and the height of the protruding portion 21A.1 corresponds to the depth of the recess 33C.1.

In all the embodiments shown in FIGS. 4A to 4C the respective lengths of the recesses and protruding portions perpendicular to the drawing plane may extend along the entire length of the respective bent-back portion.

FIG. 5 comprises FIG. 5A to 5C and shows different kinds of clips to be used in a semiconductor device according to the first aspect.

FIG. 5A shows a clip as was shown in the embodiments of FIGS. 2 and 3, namely a clip comprising a C shape. FIGS. 4B and 4C show clips comprising different forms. These different forms show that the bent-back portion of the clip does not necessarily have to have the form of a horizontal bar as in Fin FIG. 4.

### EXAMPLES

In the following specific examples of the present disclosure are described.

Example 1 is a semiconductor device comprising a semiconductor die disposed on the carrier and comprising a first contact pad on a first main face remote from the carrier, and a clip connected between the contact pad and the carrier, wherein the clip comprises a horizontal portion, a vertical portion, and a bent-back portion.

Example 2 is a semiconductor device according to Example 1, wherein the horizontal portion is connected with the contact pad, and the bent-back portion is connected with the carrier.

Example 3 is a semiconductor device according to Example 1, wherein the clip further comprises a further vertical portion which is connected with the horizontal portion and with a portion of the carrier, and wherein the bent-back portion is connected with the contact pad.

Example 4 is a semiconductor device according to any one of the preceding Examples, wherein the carrier comprises a leadframe comprising a die pad and one or more leads.

Example 5 is a semiconductor device according to any one of the preceding Examples, further comprising an encapsulant covering at least parts of the semiconductor die, the carrier, and the clip.

Example 6 is a semiconductor device according to Example 5, wherein the encapsulant covers an outer sidewall of the vertical portion of the clip.

Example 7 is a semiconductor device according to Example 3 or 4, wherein the bent-back portion is covered by the encapsulant.

Example 8 is a semiconductor device according to any one of the preceding Examples, wherein the carrier comprises a carrier connection portion for connecting with the bent-back portion of the clip.

Example 9 is a semiconductor device according to Example 8, wherein the carrier connection portion comprises a recess for receiving the bent-back portion of the clip.

Example 10 is a semiconductor device according to any one of the preceding Examples, wherein a surface of the horizontal portion of the clip is exposed to the outside.

Example 11 is a semiconductor device according to any one of the preceding Examples, wherein the bent-back portion of the clip comprises a horizontal shape.

Example 12 is a semiconductor device according to any one of the preceding Examples, wherein the semiconductor die comprises a semiconductor transistor die.

Example 13 is a semiconductor device according to Example 12, wherein the semiconductor die comprises one or more of a horizontal semiconductor transistor die, a vertical semiconductor transistor die, a semiconductor power transistor die, an IGBT die, a MOSFET die, a CoolMOS die, a wide band gap semiconductor transistor die, in particular a SiC transistor die or a GaN transistor die.

Example 14 is a semiconductor device according to any one of the preceding Examples, wherein the semiconductor die comprises a second contact pad on the first main face.

Example 15 is a semiconductor device according to Example 14, further comprising a further clip connected between the second contact pad and the carrier.

Example 16 is a semiconductor device according to Example 15, wherein the carrier comprises a leadframe comprising a die pad and one or more leads, and the clip is connected with the die pad and the further clip is connected to a lead.

Example 16 is a semiconductor device Example 15 or 16, wherein the further clip is similar in shape to the clip.

Example 17 is a method for fabricating a semiconductor device, the method comprising providing a carrier, disposing a semiconductor die on the carrier, the semiconductor die comprising a first contact pad on a first main face remote from the carrier, providing a clip comprising a horizontal portion, a horizontal portion, an adjoining vertical portion, and an adjoining a bent-back portion connected with the carrier, and connecting the clip between the semiconductor die and the carrier by connecting the horizontal portion with the contact pad and the bent-back portion with the carrier.

Example 19 is a method according to Example 18, wherein providing the carrier comprises forming a carrier connection portion into the carrier, the recess being configured to connect with the bent-back portion of the clip.

Example 20 is a method according to Example 19, wherein the carrier connection portion comprises a recess configured to receive the bent-back portion of the clip.

Example 21 is a method according to Example 20, wherein forming the recess comprises one of coining, milling or etching.

Example 22 is a method according to any one of Examples 17 to 21, further comprising covering at least parts of the semiconductor die, the carrier, and the clip with an encapsulant.

Example 23 is a method according to Example 20, further comprising covering an outer sidewall of the vertical portion of the clip with the encapsulant.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A semiconductor device comprising:
a carrier;
a semiconductor die disposed on the carrier and comprising a first contact pad on a first main face remote from the carrier; and
a clip connected between the contact pad and the carrier, wherein the clip comprises a horizontal portion, a vertical portion, and a bent-back portion.

2. The semiconductor device according to claim 1, wherein
the horizontal portion is connected with the contact pad, and the bent-back portion is connected with the carrier.

3. The semiconductor device according to claim 1, wherein
the clip further comprises a further vertical portion which is connected with the horizontal portion and with a portion of the carrier, and wherein
the bent-back portion is connected with the contact pad.

4. The semiconductor device according to claim 1, wherein
the carrier comprises a leadframe comprising a die pad and one or more leads.

5. The semiconductor device according to claim 1, further comprising
an encapsulant covering at least parts of the semiconductor die, the carrier, and the clip.

6. The semiconductor device according to claim 5, wherein
the encapsulant covers an outer sidewall of the vertical portion of the clip.

7. The semiconductor device according to claim 3, wherein
the bent-back portion is covered by the encapsulant.

8. The semiconductor device according to claim 1, wherein
the carrier comprises a carrier connection portion for connecting with the bent-back portion of the clip.

9. The semiconductor device according to claim 8, wherein
the carrier connection portion comprises a recess for receiving the bent-back portion of the clip.

10. The semiconductor device according to claim 1, wherein
a surface of the horizontal portion of the clip is exposed to the outside.

11. The semiconductor device according to claim 1, wherein
the bent-back portion of the clip comprises a horizontal shape.

12. The semiconductor device according to claim 1, wherein
the semiconductor die comprises a semiconductor transistor die.

13. The semiconductor device according to claim 12, wherein
the semiconductor die comprises one or more of a horizontal semiconductor transistor die, a vertical semiconductor transistor die, a semiconductor power transistor die, an IGBT die, a MOSFET die, a CoolMOS die, a wide band gap semiconductor transistor die, in particular a SiC transistor die or a GaN transistor die.

14. The semiconductor device according to claim 1, wherein
the semiconductor die comprises a second contact pad on the first main face.

15. The semiconductor device according to claim 14, further comprising a further clip connected between the second contact pad and the carrier.

16. The semiconductor device according to claim 15, wherein
the carrier comprises a leadframe comprising a die pad and one or more leads, and the clip is connected with the die pad and the further clip is connected to a lead.

17. The semiconductor device according to claim 15, wherein
the further clip is similar in shape to the clip.

18. A method for fabricating a semiconductor device, the method comprising
providing a carrier;
disposing a semiconductor die on the carrier, the semiconductor die comprising a first contact pad on a first main face remote from the carrier;
providing a clip comprising a horizontal portion, a horizontal portion, an adjoining vertical portion, and an adjoining a bent-back portion connected with the carrier; and
connecting the clip between the semiconductor die and the carrier by connecting the horizontal portion with the contact pad and the bent-back portion with the carrier.

19. The method according to claim 18, wherein
providing the carrier comprises forming a carrier connection portion into the carrier, the recess being configured to connect with the bent-back portion of the clip.

20. The method according to claim 19, wherein
the carrier connection portion comprises a recess configured to receive the bent-back portion of the clip.

21. The method according to claim 20, wherein
forming the recess comprises one of coining, milling or etching.

22. The method according to claim 17, further comprising
covering at least parts of the semiconductor die, the carrier, and the clip with an encapsulant.

23. The method according to claim 20, further comprising
covering an outer sidewall of the vertical portion of the clip with the encapsulant.
